(19) United States
(12) Patent Application Publication
(10) Pub. No.: US 2026/0068152 A1
(43) Pub. Date: Mar. 5, 2026

(54) Antifuse One-Time Programmable Memory and Manufacturing Method Thereof

(71) Applicant: Donghyuk Ju, Seattle, WA (US)

(72) Inventor: Donghyuk Ju, Seattle, WA (US)

(21) Appl. No.: 18/822,306

(22) Filed: Sep. 2, 2024

(51) Int. Cl. H10B 20/25; G11C 17/16; H01L 23/525

(52) U.S. Cl. CPC H10B 20/25; G11C 17/16

(57) ABSTRACT

An antifuse OTP memory bit cell comprises a gate electrode, a gate dielectric, a bit line diffusion, and source/drain diffusions formed in an active area of a semiconductor substrate. The bit line diffusion is of the same doping type as source/drain diffusion and is created by a doping process before the gate electrode is formed. The gate electrode is of the opposite doping type to the bit line diffusion and forms a rectifying junction with the bit line diffusion when a bit cell is programmed.

### CROSS-REFERENCE TO RELATED APPLICATIONS

N/A

### FIELD OF THE INVENTION

The present invention generally relates to semiconductor memory, specifically to antifuse one-time programmable memory.

### BACKGROUND OF THE INVENTION

Antifuse is an electrical device that conducts little current in an unprogrammed state and large current when programmed. The electrical characteristics of an antifuse in unprogrammed and programmed states are opposite to those of a fuse, hence the name antifuse. The non-conducting and conducting states of an antifuse can be used to store digital data “0” and “1”, i.e., a memory device can be built with an antifuse.

A common method of making an antifuse in a semiconductor chip uses a thin dielectric layer sandwiched between two conducting materials or electrodes. In an unprogrammed antifuse—its natural state—the dielectric layer blocks current flow between the two electrodes. To program an antifuse, a high voltage is applied to the antifuse to cause dielectric breakdown. After the dielectric breakdown, the antifuse can conduct current, i.e., the antifuse is programmed.

Programming of an antifuse permanently changes its electrical properties. Once programmed, an antifuse cannot revert to an unprogrammed state. Therefore, a memory device fabricated with an antifuse can be programmed only once, i.e., a one-time programmable (OTP) memory. Antifuse OTP memory retains data after power is turned off, so it belongs to a group of semiconductor memories classified as non-volatile memory (NVM).

Antifuse OTP memory is often embedded in integrated circuit (IC) chips to store program codes, and security codes, trim analog circuits, and repair dynamic random-access memory (DRAM), to name just a few. It is an important part of digital, analog, and mixed-signal integrated circuits and is used extensively in consumer, industrial, automotive, and internet-of-things (IoT) applications.

Antifuse OTP memory when fabricated with a complementary metal-oxide-semiconductor (CMOS) process—the mainstream IC manufacturing process today—typically has one transistor and one capacitor (1T1C) in a bit cell. The capacitor, an antifuse, is in the form of a metal-oxide-semiconductor (MOS). A MOS field-effect transistor (MOSFET) in a bit cell is used to access data stored in the antifuse. The advantages of 1T1C OTP memory over other types of OTP memory, electrical fuse for example, are a small bit cell size, high reliability, excellent data security, and ease of user programmability and scalability.

A schematic circuit of an exemplary antifuse 1T1C bit cell is shown in FIG. 1A, a prior art. An N-channel MOSFET and a MOS capacitor are shown inside circles 101 and 102 of FIG. 1A, respectively. The gates of the MOSFET and MOS capacitor are connected and serve as the word line (WL), and the source of the MOSFET is the bit line (BL). FIG. 1A illustrates schematically that the MOSFET is a thick gate dielectric device such as those used in input/output circuits of IC chips, and the MOS capacitor is a thin gate dielectric device used for core circuits in logic ICs.

FIG. 1B is a cross-sectional drawing of FIG. 1A when fabricated with an exemplary CMOS process. Inside circle 103 of FIG. 1B is an N-channel MOSFET comprising N⁺ source 104, N⁺ gate polysilicon 105, a thick gate dielectric 106, N⁺ drain 112, and a P-type substrate 100. The N⁺ source and drain diffusions extend into the MOSFET channel with a high-voltage lightly doped drain (N_{hvldd}) 107. The MOS capacitor inside circle 108 comprises N⁺ gate polysilicon 109, a thin gate dielectric 110, and a low-voltage lightly doped drain (N_{lvldd}) 111. The MOS capacitor borders the N⁺ drain 112 on one side and shallow trench isolation (STI) 113 on the other.

Breakdown of the thin gate dielectric 110 of the MOS capacitor in FIG. 1B can occur either at the overlap region of N⁺ gate polysilicon with N_{lvldd} or at the MOS capacitor channel as illustrated in FIG. 2. If the gate dielectric breaks down in the gate-N_{lvldd} overlap region 201, N⁺ gate polysilicon is connected to N_{lvldd} with a resistor. If the gate dielectric breaks down in the MOS capacitor channel 202, a diode is formed by the N⁺ gate polysilicon and P-type MOS capacitor channel and it creates an N-channel MOSFET 203 where the gate and drain are connected.

It is clear in FIG. 1B that the access MOSFET in 1T1C bit cell will occupy a sizable portion of the total bit cell area. It is also clear from FIG. 2 that the read current of 1T1C bit cell can vary significantly since it depends on the location of gate dielectric breakdown. To meet the performance, density, and cost requirements demanded by the wide-ranging OTP memory applications, it is hoped that these shortcomings of the 1T1C bit cell will be overcome. One such attempt is disclosed in a prior art found in U.S. Pat. No. 8,330,189 by H. Luan, et al. FIG. 3A and FIG. 3B are the cross-sectional drawings therein. The bit cell described in this prior art is small, however, it requires added manufacturing steps and careful optimization of them, increasing the manufacturing cost. Moreover, there is an inherent bit-cell-to-bit-cell performance variation due to the buried bit line. Another such attempt is disclosed in U.S. Pat. No. 9,142,316 by Y. Liu, et al. The bit cell disclosed therein uses N-well in the CMOS process as bit line diffusion. Since N-well junctions are deep, this bit cell requires a large spacing between bit lines and as a result, a compact bit cell is difficult to attain. U.S. Pat. No. 11,152,382 by D. Ju overcomes these shortcomings of the aforementioned prior arts by using lateral diffusion of dopants from the source and drain to form bit line diffusion. FIG. 4 therein is reproduced as FIG. 4 herein with the bit line junction profile under the gate magnified. Though U.S. Pat. No. 11,152,382 overcomes the shortcomings of the aforementioned prior arts, its ability to meet the electrical characteristics demanded by low-power high-density memory applications is limited as explained below. Note in FIG. 4 that the junction depth of the bit line diffusion is shown to vary laterally along the channel, a result of varying bit line doping concentration in the lateral direction. The bit line diffusion doping profile determines forward diode characteristics of a programmed bit cell such as diode turn-on voltage and read current. Likewise, the bit line diffusion doping profile influences the diode reverse leakage current and breakdown voltage. In particular, the reverse leakage current of a Schottky diode formed in a programmed bit cell by a metal gate CMOS process is sensitive to the bit line diffusion doping profile. This is because the leakage current is due not only to carrier generation within the depletion region of the metal-to-semiconductor junction but also to the tunneling of electrons through the energy barrier assisted by traps existing at the metal-to-semiconductor interface. The varying lateral bit line doping profile along the channel shown in FIG. 4 results in varying electrical characteristics of programmed bit cells. Therefore, an improvement over U.S. Pat. No. 11,152,382 is desired.

### BRIEF SUMMARY OF THE INVENTION

An antifuse OTP memory bit cell comprises a MOS capacitor formed by a gate electrode, a thin gate dielectric, and an active area in a semiconductor substrate. The gate electrode is the word line and of the opposite doping type to the active area. Source/drain and channel regions in the active area are of the same doping type and form a continuous bit line diffusion. The bit line diffusion doping profile is laterally uniform along the channel. The source and drain are heavily doped and connected to a metal bit line that runs orthogonally to the gate electrode which is the word line.

### BRIEF DESCRIPTION OF THE DRAWINGS

FIG. 1A and FIG. 1B are schematic and cross-sectional drawings of the one-transistor one-capacitor (1T1C) antifuse OTP memory bit cell found in the prior art.

FIG. 2 is a cross-sectional drawing of the MOS capacitor in the 1T1C bit cell wherein the two distinguishable locations of gate dielectric breakdown are shown.

FIG. 3A and FIG. 3B are cross-sectional drawings of the antifuse OTP memory bit cell disclosed in U.S. Pat. No. 8,330,189, a prior art.

FIG. 4 is a cross-sectional drawing of the antifuse OTP memory bit cell disclosed in U.S. Pat. No. 11,152,382, a prior art.

FIG. 5 is an exemplary cross-sectional drawing of an antifuse OTP memory bit cell according to one embodiment of the present invention.

FIG. 6A and FIG. 6B are exemplary doping profiles of the bit line diffusions in the horizontal direction along the channel for the present invention and U.S. Pat. No. 11,152,382, respectively.

FIG. 7A and FIG. 7B are schematic representations of the bit cell of FIG. 5 in an unprogrammed and a programmed state, respectively.

FIG. 8 is a three-dimensional view of an antifuse OTP memory bit cell according to another embodiment of the present invention wherein the bit cell is realized in a silicon fin using a 3-dimensional MOSFET CMOS process.

FIG. 9 is a top view of an exemplary layout of a 3×3 memory array designed with the embodiment of the present invention shown in FIG. 5.

FIG. 10A and FIG. 10B are cross-sectional views of FIG. 9 along the bit line direction and the word line direction, respectively.

FIG. 11 is an exemplary schematic circuit and bias condition for a program mode of a 3×3 memory array built with the embodiment of FIG. 5.

FIG. 12 is an exemplary schematic circuit and bias condition for a read mode of a 3×3 memory array built with the embodiment of FIG. 5.

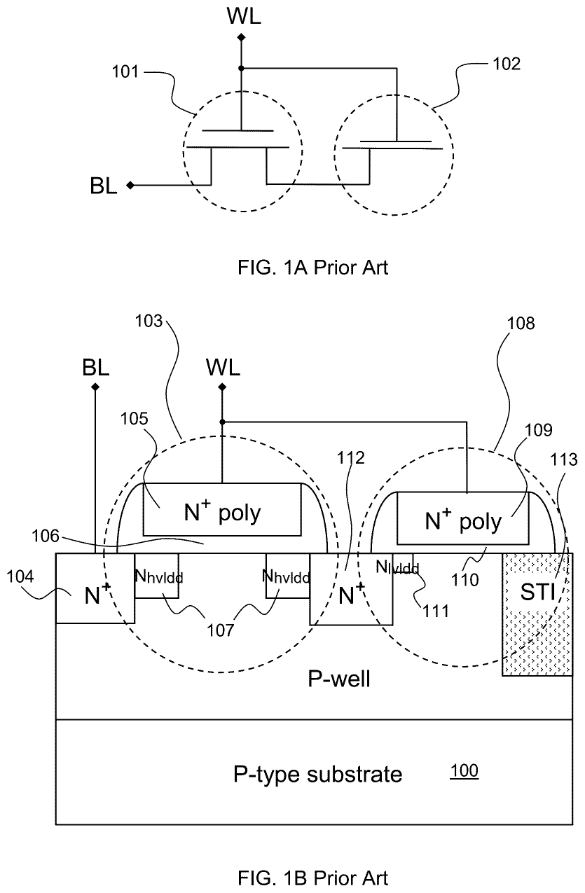

### DETAILED DESCRIPTION OF THE INVENTION

The present invention employs a bit line implant to form bit line diffusion. The bit line implant is performed before the formation of the gate electrode, thus uniformly doping an entire active area. As a result, the present invention delivers uniform electrical characteristics of the diode in programmed bit cells irrespective of the location of dielectric breakdown in the channel. In contrast, the bit line doping profile of U.S. Pat. No. 11,152,382 varies along the channel causing the diode's electrical characteristics to vary depending on the location of dielectric breakdown.

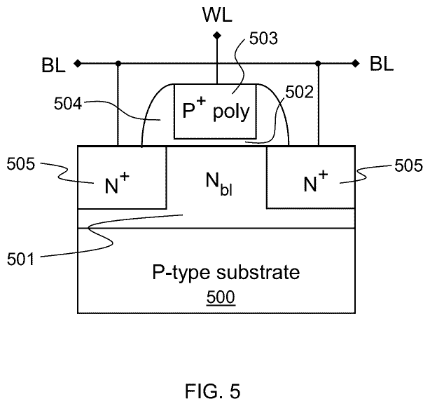

FIG. 5 is a cross-sectional view of an antifuse OTP memory bit cell according to one embodiment of the present invention. Substrate 500 is a P-type non-epitaxial silicon wafer, wherein the substrate doping concentration is 2.0×10¹⁵/cm³˜2.0×10¹⁶/cm³, a doping concentration commonly found in non-epitaxial silicon wafers. Active areas are defined when shallow trench isolation (STI)—not seen along the cut direction of FIG. 5—is formed. STI is typically 0.25 micrometers (um) to 0.35 um deep and filled with silicon dioxide. An N-type bit line ion implantation is carried out into the active area in the memory array, which later forms bit line diffusion N_{bl} 501 when processing is complete. The bit line ion implant may use phosphorus as implant species with an implant dosage of 5.0×10¹²/cm² to 5.0×10¹³/cm² and implant energy of 20-kilo electron-Volt (KeV) to 50 KeV. After the bit line ion implant, the standard CMOS process continues with gate dielectric growth, gate electrode deposition, and patterning. The material composition and thickness of gate dielectric 502 depend on the operating voltage. The gate dielectric can be silicon dioxide (SiO₂) or a high-k dielectric such as hafnium oxide (HfO₂). For an operating voltage from 1V to 1.8V, gate dielectric thickness ranges from one nanometer (nm) to 3 nm. The gate electrode 503 is a boron-doped P⁺ polysilicon with a typical doping concentration of 2.0×10²/cm³˜5.0×10²¹/cm³. For a metal gate CMOS process, the gate electrode 503 is a metal having a P-channel work function. After gate patterning, a standard CMOS process proceeds with an ion implant for a lightly doped drain (LDD), also known as source/drain extension. In the present invention, the LDD implant is blocked from the memory array to ensure a uniform lateral doping profile of the bit line diffusion in the channel. If the LDD implant is lighter than the bit line ion implant, the LDD implant may be allowed in the memory array, thus lessening the deviation from the standard CMOS process. After the LDD ion implant, the process proceeds with the formation of gate sidewall spacer 504 followed by an ion implant for source/drain 505 using arsenic with a typical dosage of 2.0×10¹⁵/cm²˜5.0×10¹⁵/cm² and implant energy of 25 KeV˜45 KeV. After the sour/drain implant, the process continues with the standard CMOS process for the back end of the flow.

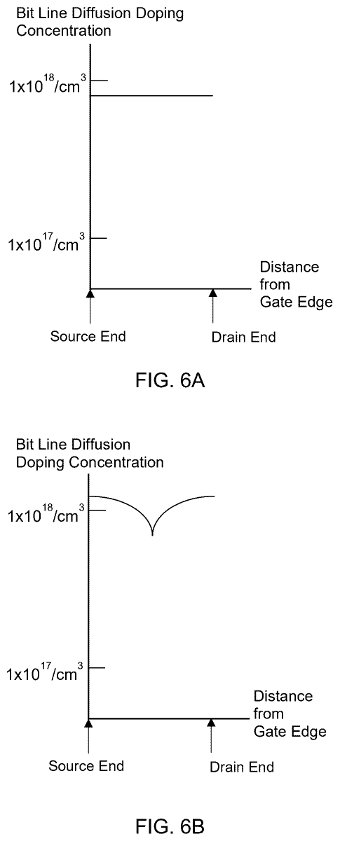

As noted above, the doping concentration of the bit line diffusion in the present invention varies only in the vertical direction, i.e., from the silicon surface downward into the silicon. The doping concentration at a given depth in silicon is the same in the horizontal direction along the channel as illustrated in FIG. 6A. This uniform horizontal doping concentration helps improve bit cell electrical characteristics as explained above. In contrast, the doping profile of the bit line diffusion in the channel of U.S. Pat. No. 11,152,382 varies not only in the vertical direction but also horizontally in the channel as illustrated in FIG. 6B. Because of this, bit cell electrical characteristics can vary as explained above.

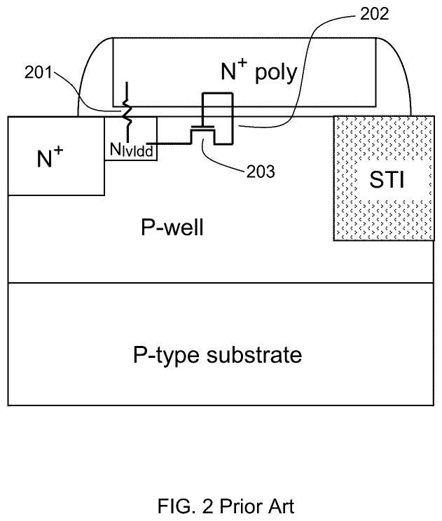

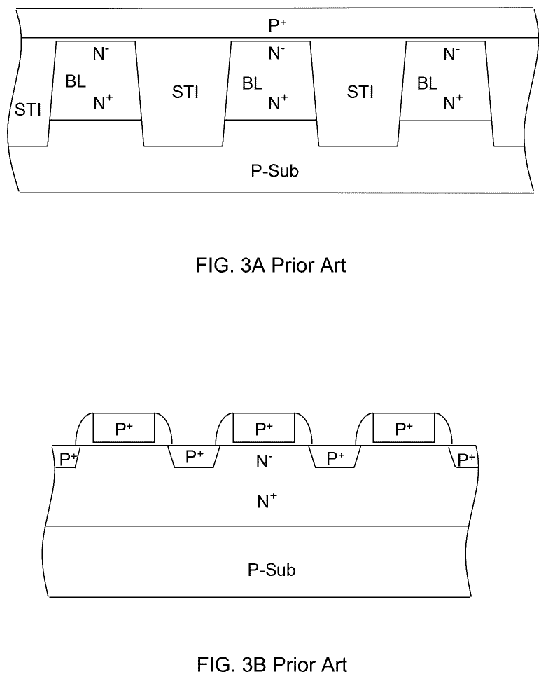

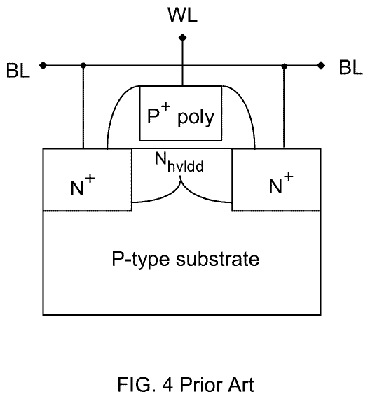

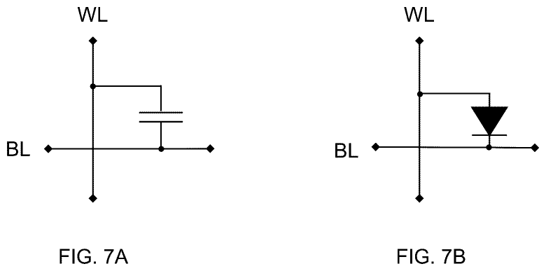

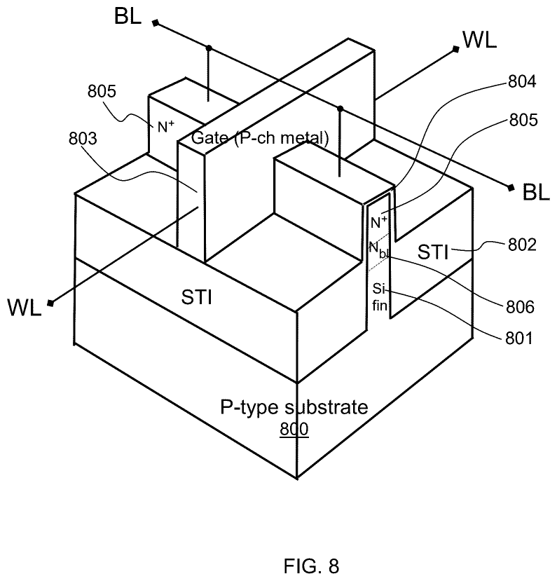

FIG. 7A is a schematic representation of an unprogrammed bit cell of the present invention, wherein the bit cell is depicted as a capacitor. FIG. 7B is a schematic representation of a programmed bit cell. It should be noted that in FIG. 7B the programmed bit cell is depicted as a diode irrespective of the location of the gate dielectric breakdown in the channel. This should be contrasted with the 1T1C bit cell schematics shown in FIG. 2, where the schematic representation of a programmed antifuse depends on the location of gate dielectric breakdown.

During read mode, if a selected bit cell is programmed, current flows from the selected word line to the selected bit line through the forward-biased diode of FIG. 7B. If the selected bit cell is unprogrammed, little current flows from the selected word line to the selected bit line as the capacitor of FIG. 7A blocks current flow. As it will become clear later in the disclosure where details of the bit cell program and read operations are described, the bit cell of the present invention is addressable with only a MOS capacitor in the bit cell and not requiring a separate access transistor.

Note that the embodiment of FIG. 5 was presented using a P-type substrate without mentioning a P-well. However, it would be clear to those of ordinary skill in the art that the bit cell can be realized inside a P-well in a P-type substrate or inside a P-well isolated by a deep N-well in a P-type substrate. It should also be mentioned while a P-type substrate was used in the exemplary embodiment of FIG. 5 and will be used throughout the disclosure for consistency, those of ordinary skill in the art will understand the bit cell can be realized using an N-type substrate or inside an N-well formed in a P-type substrate with an appropriate reversal of conductivity types for diffusion regions. It should also be mentioned whereas the embodiment of FIG. 5 was presented using a non-epitaxial wafer, those of ordinary skill in the art will recognize the bit cell can be realized with an epitaxial wafer and a silicon-on-insulator (SOI) wafer.

It is to be noted that the horizontal and vertical dimensions of the various regions in FIG. 5 and other drawings of this disclosure, including the thicknesses of layers, depth and lateral reach of doped regions, and relative lengths are not necessarily drawn to scale. In some cases, layer thicknesses, junction depths, lengths, and other dimensions are exaggerated to best illustrate the structural features and/or functional aspects of the present invention. It should also be mentioned that not all features employed by the standard CMOS process and known to those of ordinary skill in the art are described to avoid obfuscation of the key aspects of the disclosure.

Starting at around the 30 nm node of the CMOS process, the metal replaces polysilicon as the gate material. At such process nodes, the gate depletion effect occurring in polysilicon gates significantly increases the effective gate dielectric thickness and impedes MOSFET scaling. The metal gate does not suffer from gate depletion and therefore using a metal gate is essential for MOSFET scaling at advanced CMOS nodes. In a dual metal gate CMOS process, two distinct metals with different work functions are used: one for the gate of N-channel MOSFET and the other for the gate of P-channel MOSFET to obtain respective threshold voltages. Therefore, the metal gates of N-channel MOSFET and P-channel MOSFET in a dual metal gate CMOS process play a similar role to N⁺ polysilicon gate and P⁺ polysilicon gate in silicon gate CMOS technology. Hence, the bit cell of the present invention can also be realized in a dual metal gate CMOS process by using appropriate metal.

The short-channel effects in two-dimensional (2D) MOSFETs are a barrier to continued scaling at advanced CMOS nodes. Below the 20 nm node, CMOS technology begins to migrate from the conventional 2D planar MOSFET to three-dimensional (3D) MOSFET. Fin-FET is an early version of the 3D MOSFET, and a more advanced version referred to as gate-all-around (GAA) MOSFET, also known as nanosheet MOSFET, will soon emerge as a production-worthy 3D CMOS device. In a Fin-FET CMOS process, MOSFETs are formed in a thin slice of semiconductor material protruding from the semiconductor substrate and the gate electrode wraps around the fin. As a result, the short-channel effects are mitigated, and the device scaling can continue. FIG. 8 is a 3D view of a bit cell of the present invention wherein the bit cell is formed using a Fin-FET structure. In an exemplary Fin-FET bit cell of FIG. 8, a P-type silicon fin 801 is shaped on a P-type substrate 800 and is isolated from the adjacent silicon fins by shallow trench isolation (STI) 802. The gate electrode 803 is a P-channel metal and wraps around the silicon fin 801 underneath the gate dielectric 804. The gate is the word line and runs orthogonally to the silicon fin. The N⁺ source/drain diffusions 805 are formed in the silicon fin on both sides of the gate and are connected to a metal bit line (not shown) that runs parallel to the silicon fin. An N-type bit line diffusion N_{bl} 806 inside the silicon fin under the gate connects the N⁺ source/drain diffusions on the opposite sides of the gate.

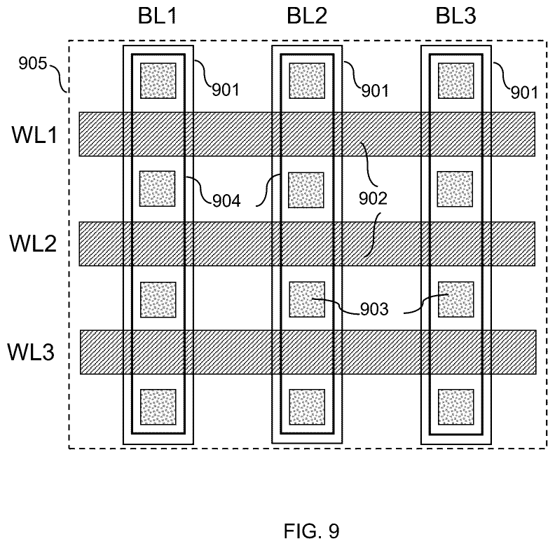

FIG. 9 is a top view of an exemplary layout of a 3×3 memory array using the embodiment of the present invention shown in FIG. 5. The active areas 901 are laid out in the vertical direction and the polysilicon gates 902 are laid out in the horizontal direction but their orientations can be interchanged. The bit line implant pattern 905 covers the entire memory array. N⁺ diffusions in an active area are connected to a metal 904 through contacts 903 forming the bit line and the gate is the word line. The array layout is such that a bit cell exists at each intersection of a word line and a bit line.

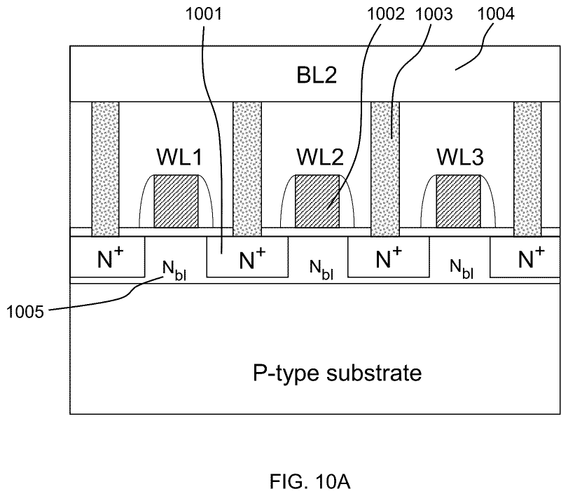

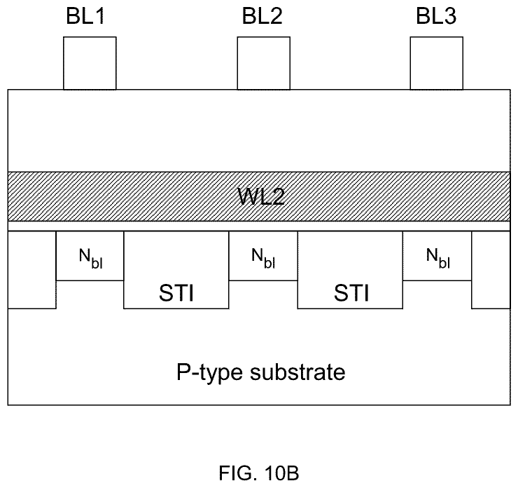

FIG. 10A and FIG. 10B are the cross-sectional drawings of FIG. 9 along the bit line and the word line, respectively. FIG. 10A shows that all N⁺ diffusions 1001 in a bit line are connected to the metal bit line BL2 1004 through contact holes 1003 but they don't have to be. Since the N⁺ diffusions are connected under gate 1002 by bit line diffusion N_{bl} 1005, a metal bit line can connect to the N⁺ diffusions only as often as needed, for example, every other N⁺ diffusion, thus saving the array area as long as the memory performance is not compromised.

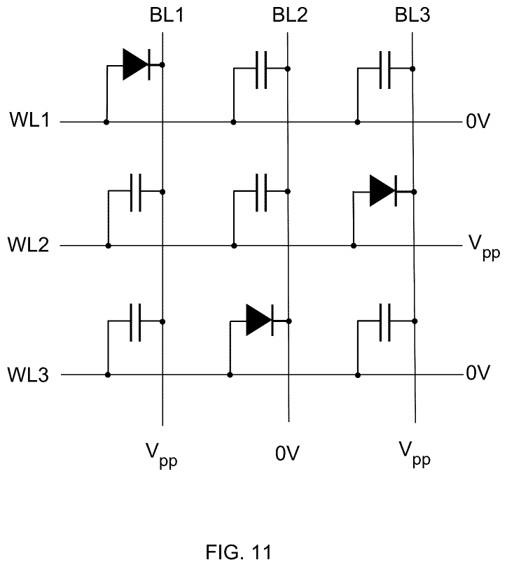

FIG. 11 is a schematic circuit of a 3×3 memory array with an exemplary bias condition for program mode according to the embodiment of the present invention shown in FIG. 5. An unprogrammed bit cell is represented by a capacitor and a bit cell that had already been programmed is represented by a diode. To program the bit cell found at WL2/BL2, a positive program voltage Vₚₚ is applied to the selected word line WL2, and 0V is applied to the selected bit line BL2. The unselected word lines WL1 and WL3 are biased to 0V and the unselected bit lines BL1 and BL3 are biased to Vₚₚ. The value of Vₚₚ depends on the thickness and strength of the gate dielectric. It ranges from ˜3V for a CMOS node of 14 nm to ˜6V for a 65 nm node. Under the given bias condition, the MOS capacitor channel of the selected bit cell at WL2/BL2 is accumulated with electrons and the bit cell is programmed by gate dielectric breakdown. In unselected unprogrammed bit cells such as those found at WL1/BL2 and WL3/BL3, the MOS capacitor channels are either at the same voltage as the gate or in a deep depletion mode, so those bit cells are not programmed. In unselected programmed bit cells located at WL1/BL1 and WL2/BL3, the diode is reverse-biased or the voltage across the diode is 0V. Thus, they draw little or no current and do not disrupt the programming of the bit cell located at WL2/BL2.

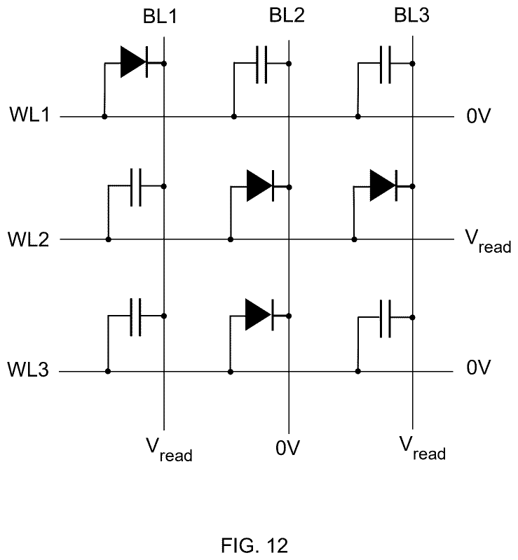

FIG. 12 is a schematic circuit of a 3×3 memory array with an exemplary bias condition for read mode according to the embodiment of the present invention shown in FIG. 5. To read the bit cell found at WL2/BL2, a positive read voltage V_{read} is applied to the selected word line WL2 and 0V is applied to the selected bit line BL2. The unselected word lines WL1 and WL3 are biased to 0V and the unselected bit lines BL1 and BL3 are biased to V_{read}. Since the diode turn-on voltage is ˜0.7V for a silicon PN junction diode, a typical value of V_{read} ranges from 0.7V to 1.5V. Under the given bias condition, the diode at WL2/BL2 is forward-biased, and current flows from WL2 to BL2. The voltages across diodes in unselected programmed bit cells found at WL3/BL2 and WL1/BL1 are 0V and-V_{read}, respectively so no or little current flows between the word line and bit line.

It should be understood that presentations have been made by way of example, and not limitation. It will be clear to people skilled in the relevant art that various changes in form and detail may be made therein without departing from the spirit and scope of the invention. Therefore, the scope of the invention should be decided not concerning the above description, but instead by reference to the appended claims, along with the full scope of equivalents to which such claims are entitled.

What is claimed is:

1. A semiconductor one-time programmable memory bit cell comprising:
an active area of a first conductivity type disposed in a semiconductor substrate,
a gate dielectric layer disposed over said active area,
a gate electrode disposed over the said gate dielectric and across said active area,
a diffusion layer of a second conductivity type created in the said active area by a doping process performed before the formation of the said gate electrode,
diffusion regions of the second conductivity type disposed in the said active area not covered by the said gate electrode,
a metal line connected to the said diffusion regions of the second conductivity type through contact holes disposed on said diffusion regions, and
shallow trench isolation (STI) disposed in the said semiconductor substrate,
wherein the said gate electrode forms a rectifying junction with said diffusion layer of the second conductivity type after a breakdown of the said gate dielectric, said metal line is a bit line extending in the direction of said active area, said gate electrode is a word line extending in the direction orthogonal to the said metal line, and said active area is separated from neighboring active areas by said STI.

2. The memory bit cell of claim 1 wherein the first conductivity type is P-type, and the second conductivity type is N-type.

3. The memory bit cell of claim 1 wherein the first conductivity type is N-type, and the second conductivity type is P-type.

4. The memory bit cell of claim 1 wherein said gate electrode is a polysilicon of the first conductivity type in a polysilicon gate CMOS process.

5. The memory bit cell of claim 1 wherein said gate electrode is metal used as the gate of MOSFETs of which source/drain diffusions are of the first conductivity type in a metal gate CMOS process.

6. The memory bit cell of claim 1 wherein the said doping process for said diffusion layer of the second conductivity type is ion implantation.

7. The memory bit cell of claim 1 wherein lightly doped drain implant or source/drain extension implant is blocked from the bit cell area.

8. The memory bit cell of claim 1 wherein lightly doped drain implant or source/drain extension implant is performed in the bit cell area.

9. The memory bit cell of claim 1 wherein said metal line makes contact to every said diffusion region of the second conductivity type not covered by said gate electrode in said active area.

10. The memory bit cell of claim 1 wherein said metal line makes contact only as often as needed to said diffusion regions of the second conductivity type not covered by said gate electrode in said active area.

11. The memory bit cell of claim 1 wherein the said active area is disposed in a portion of said semiconductor substrate having an intrinsic substrate doping concentration.

12. The memory bit cell of claim 1 wherein the said active area is disposed inside a well of the first conductivity type disposed in the said semiconductor substrate.

13. The memory bit cell of claim 1 wherein the bit cell is a two-dimensional MOS structure.

14. The memory bit cell of claim 1 wherein the bit cell is a three-dimensional MOS structure.

15. The memory bit cell of claim 1 wherein the said semiconductor substrate is a bulk silicon wafer.

16. The memory bit cell of claim 1 wherein the said semiconductor substrate is an epitaxial silicon wafer.

17. The memory bit cell of claim 1 wherein the said semiconductor substrate is a silicon-on-insulator wafer.
